(19) United States
(12) Patent Application Publication
(10) Pub. No.: US 2024/0164174 A1
(43) Pub. Date: May 16, 2024

(54) DISPLAY SUBSTRATE AND DISPLAY DEVICE

(71) Applicants: Chengdu BOE Optoelectronics Technology Co., Ltd., Chengdu, Sichuan Province (CN); BOE Technology Group Co., Ltd., Beijing (CN)

(72) Inventor: Puyu QI, Beijing (CN)

(21) Appl. No.: 18/578,339

(22) PCT Filed: Aug. 25, 2021
(86) PCT No.: PCT/CN2021/114483

§ 371 Date: Jan. 11, 2024

(51) Int. Cl. H10K 59/50; H10K 59/122; H10K 59/38; H10K 59/80

(52) U.S. Cl. CPC H10K 59/50; H10K 59/122; H10K 59/38; H10K 59/8792; H10K 59/8793

(57) ABSTRACT

The present disclosure provides a display substrate and a display device. The display substrate includes a base substrate; light-emitting devices of a plurality of colors arranged in an array on the base substrate; an anti-reflection layer on the side of the layer where the light-emitting device is away from the base substrate; and a chiral liquid crystal layer between the layer where the light-emitting device is and the anti-reflection layer, wherein the orthographic projection of the chiral liquid crystal layer on the base substrate overlaps the orthographic projection of a light-emitting device of at least one color on the base substrate; the central reflection wavelength of the chiral liquid crystal layer is roughly the same as the light-emitting wavelength of the light-emitting device of at least one color overlapping the chiral liquid crystal layer, and the helix direction of the chiral liquid crystal layer is left-handed helix or right-handed helix.

### TECHNICAL FIELD

The present disclosure relates to the field of display technology, and in particular to a display substrate and a display device.

### BACKGROUND

In recent years, the Organic Light-Emitting Displays (OLEDs), as a new type of flat panel display, have gradually received more attention. Due to its excellent characteristics such as active light emission, high luminous brightness, high resolution, wide viewing angle, fast response speed, small thickness, low energy consumption, flexibility, wide operating temperature range, simple structure and process, it has broad application prospects.

### SUMMARY

The solutions of the display substrate and display device provided by embodiments of the present disclosure are as follows.

In one aspect, embodiments of the present disclosure provide a display substrate, including:
a base substrate;
a plurality of light-emitting devices with a plurality of colors, arranged in an array on the base substrate;
an anti-reflection layer, arranged on a side of a layer where the light-emitting devices are located facing away from the base substrate; and
a chiral liquid crystal layer, arranged between the layer where the light-emitting devices are located and the anti-reflection layer;
where an orthographic projection of the chiral liquid crystal layer on the base substrate overlaps with an orthographic projection of at least one color light-emitting device on the base substrate;
a central reflection wavelength of the chiral liquid crystal layer is approximately same as an emission wavelength of the at least one color light-emitting device overlapping with the chiral liquid crystal layer; and
a spiral direction of the chiral liquid crystal layer is left-handed or right-handed.

In some embodiments, in the above-mentioned display substrate provided by the embodiment of the present disclosure, the plurality of light-emitting devices include a first light-emitting device, a second light-emitting device and a third light-emitting device with different colors;
where a lifetime decay rate of the first light-emitting device, a lifetime decay rate of the second light-emitting device and a lifetime decay rate of the third light-emitting device increase sequentially; and
the orthographic projection of the chiral liquid crystal layer on the base substrate at least overlaps with an orthographic projection of the third light-emitting device on the base substrate.

In some embodiments, in the above-mentioned display substrate provided by the embodiment of the present disclosure, the orthographic projection of the chiral liquid crystal layer on the base substrate and the orthographic projection of the third light-emitting device on the base substrate overlap with each other; and the orthographic projection of the chiral liquid crystal layer on the base substrate does not overlap with an orthographic projection of the first light-emitting device on the base substrate and an orthographic projection of the second light-emitting device on the base substrate.

In some embodiments, in the above-mentioned display substrate provided by the embodiment of the present disclosure, the orthographic projection of the chiral liquid crystal layer on the base substrate at least completely covers a display area of the display substrate; and
the central reflection wavelength of the chiral liquid crystal layer is approximately same as a emission wavelength of the third light-emitting device.

In some embodiments, in the above-mentioned display substrate provided by the embodiment of the present disclosure, the orthographic projection of the chiral liquid crystal layer on the base substrate overlaps with an orthographic projection of the second light-emitting device on the base substrate and an orthographic projection of the third light-emitting device on the base substrate; and the orthographic projection of the chiral liquid crystal layer on the base substrate and an orthographic projection of the first light-emitting device on the base substrate do not overlap with each other;
the central reflection wavelength of the chiral liquid crystal layer overlapped with the second light-emitting device is approximately equal to an emission wavelength of the second light-emitting device; and
the central reflection wavelength of the chiral liquid crystal layer overlapped with the third light-emitting device is approximately equal to an emission wavelength of the third light-emitting device.

In some embodiments, in the above-mentioned display substrate provided by the embodiment of the present disclosure, the orthographic projection of the chiral liquid crystal layer on the base substrate overlaps with orthographic projections of all the light-emitting devices on the base substrate;
the central reflection wavelength of the chiral liquid crystal layer overlapped with the first light-emitting device is approximately equal to an emission wavelength of the first light-emitting device;
the central reflection wavelength of the chiral liquid crystal layer overlapped with the second light-emitting device is approximately equal to an emission wavelength of the second light-emitting device; and
the central reflection wavelength of the chiral liquid crystal layer overlapped with the third light-emitting device is approximately equal to an emission wavelength of the third light-emitting device.

In some embodiments, the above-mentioned display substrate provided by the embodiment of the present disclosure, further includes: a pixel defining layer arranged on a side of the chiral liquid crystal layer facing the base substrate; where
the pixel defining layer includes a plurality of pixel openings, the light-emitting devices are located in the pixel openings; and
the orthographic projection of the chiral liquid crystal layer on the base substrate is located within an orthographic projection of the pixel opening, where the light-emitting device overlapped with the chiral liquid crystal layer is located, on the base substrate.

In some embodiments, the above-mentioned display substrate provided by the embodiment of the present disclosure, further includes: a pixel defining layer arranged on a side of the chiral liquid crystal layer facing the base substrate; where
the pixel defining layer includes a plurality of pixel openings, the light-emitting devices are located in the pixel openings; and
the orthographic projection of the chiral liquid crystal layer on the base substrate covers and is larger than an orthographic projection of the pixel opening, where the light-emitting device overlapped with the chiral liquid crystal layer is located, on the base substrate.

In some embodiments, in the above-mentioned display substrate provided by the embodiment of the present disclosure, a percentage of an area of the orthographic projection of the chiral liquid crystal layer on the base substrate to an area of the orthographic projection of the pixel opening overlapped with the chiral liquid crystal layer on the base substrate, is negatively correlated with a lifetime decay rate of the light-emitting device overlapped with chiral liquid crystal layer.

In some embodiments, the above-mentioned display substrate provided by the embodiment of the present disclosure, further includes: a pixel defining layer arranged on a side of the chiral liquid crystal layer facing the base substrate; where
the pixel defining layer includes a plurality of pixel openings, the light-emitting devices are located in the pixel openings; and
the orthographic projection of the chiral liquid crystal layer on the base substrate approximately coincides with an orthographic projection of the pixel opening, where the light-emitting device overlapped with the chiral liquid crystal layer is located, on the base substrate.

In some embodiments, in the above-mentioned display substrate provided by the embodiment of the present disclosure, an average refractive index and/or a helical pitch of the chiral liquid crystal layers overlapped with the light-emitting devices of different colors are different.

In some embodiments, in the above-mentioned display substrate provided by the embodiment of the present disclosure, spiral directions of the chiral liquid crystal layers overlapped with the light-emitting devices of different colors are same.

In some embodiments, in the above-mentioned display substrate provided by the embodiment of the present disclosure, the first light-emitting device is a red light-emitting device, the second light-emitting device is a green light-emitting device, and the third light-emitting device is a blue light-emitting device.

In some embodiments, in the above-mentioned display substrate provided by the embodiment of the present disclosure, the anti-reflection layer is a circular polarizer.

In some embodiments, the above-mentioned display substrate provided by the embodiment of the present disclosure, further includes: a light-absorbing layer arranged between the layer where the light-emitting devices are located and the chiral liquid crystal layer; and
an orthographic projection of the light-absorbing layer on the base substrate approximately coincides with an orthographic projection of a pixel defining layer on the base substrate.

In some embodiments, the above-mentioned display substrate provided by the embodiment of the present disclosure, further includes: a first inorganic encapsulation layer, an organic encapsulation layer and a second inorganic encapsulation layer arranged in sequence on a side of the light-emitting device facing the chiral liquid crystal layer;
the light-absorbing layer is arranged between the first inorganic encapsulating layer and the organic encapsulating layer, or the light-absorbing layer is arranged between the second inorganic encapsulating layer and the chiral liquid crystal layer.

In some embodiments, the above-mentioned display substrate provided by the embodiment of the present disclosure, further includes: a touch functional layer arranged between the layer where the light-emitting devices are located and the chiral liquid crystal layer; and
the light-absorbing layer is arranged between the touch function layer and the chiral liquid crystal layer.

In some embodiments, in the above-mentioned display substrate provided by the embodiment of the present disclosure, the anti-reflection layer is a color filter layer, the color filter layer includes a black matrix and a plurality of color resistors separated by the black matrix;
where orthographic projections of the color resistors on the base substrate approximately coincide with orthographic projections of the pixel openings on the base substrate, and an orthographic projection of the black matrix on the base substrate approximately coincides with an orthographic projections of the defining layer on the base substrate.

In some embodiments, in the above-mentioned display substrate provided by the embodiment of the present disclosure, an display area of the display substrate includes a left frame area and a right frame area, where a spiral direction of the chiral liquid crystal layer in the left frame area is opposite with a spiral direction of the chiral liquid crystal layer in the right frame area; and a total number of the light-emitting devices in the left frame area is equal to a total number of the light-emitting devices in the right frame area.

In some embodiments, in the above-mentioned display substrate provided by the embodiment of the present disclosure, the left frame area and the right frame area are areas on both sides of a column direction symmetry axis of the display area.

In some embodiments, in the above-mentioned display substrate provided by the embodiment of the present disclosure, the left frame area and the right frame area are alternately arranged in a row direction and/or a column direction, and each of the left frame area or each of the right frame area includes at least one of the light emitting devices.

In some embodiments, in the above-mentioned display substrate provided by the embodiment of the present disclosure, a center of the orthographic projection of the chiral liquid crystal layer on the base substrate approximately coincides with a center of an orthographic projection of the light-emitting device overlapped with the chiral liquid crystal layer on the base substrate.

On the other hand, embodiments of the present disclosure also provide a display device, including the above display substrate provided by embodiments of the present disclosure.

### BRIEF DESCRIPTION OF FIGURES

FIG. 1 is a schematic diagram of an OLED panel reflecting external natural light in related art.

FIG. 2 is a schematic structural diagram of a circular polarizer.

FIG. 3 is an anti-reflection schematic diagram of the linear polarizing layer in the circular polarizer shown in FIG. 2.

FIG. 4 is an anti-reflection schematic diagram of the linear polarizing layer combined with the quarter-wave plate layer in the circular polarizer shown in FIG. 2.

FIG. 5 is a schematic structural diagram of a display substrate provided by an embodiment of the present disclosure.

FIG. 6 is a cross-sectional structural schematic diagram along line I-II in FIG. 5.

FIG. 7 is a schematic diagram of a display substrate with a circular polarizer provided by an embodiment of the present disclosure to improve light extraction efficiency.

FIG. 8 is another cross-sectional structural schematic diagram along line I-II in FIG. 5.

FIG. 9 is another cross-sectional structural schematic diagram along line I-II in FIG. 5.

FIG. 10 is another structural schematic diagram of a display substrate provided by an embodiment of the present disclosure.

FIG. 11 is another cross-sectional structural schematic diagram along line I-II in FIG. 5.

FIG. 12 is another cross-sectional structural schematic diagram along line I-II in FIG. 5.

FIG. 13 is another cross-sectional structural schematic diagram along line I-II in FIG. 5.

FIG. 14 is another cross-sectional structural schematic diagram along line I-II in FIG. 5.

FIG. 15 is another cross-sectional structural schematic diagram along line I-II in FIG. 5.

FIG. 16 is a schematic diagram showing the impact of a display substrate with a circular polarizer on the anti-reflection effect provided by an embodiment of the present disclosure.

FIG. 17 is another cross-sectional structural schematic diagram along line I-II in FIG. 5.

FIG. 18 is another cross-sectional structural schematic diagram along line I-II in FIG. 5.

FIG. 19 is another cross-sectional structural schematic diagram along line I-II in FIG. 5.

FIG. 20 is another cross-sectional structural schematic diagram along line I-II in FIG. 5.

FIG. 21 is another cross-sectional structural schematic diagram along line I-II in FIG. 5.

FIG. 22 is a schematic diagram of a display substrate with a color filter provided by an embodiment of the present disclosure to improve light extraction efficiency.

FIG. 23 is an anti-reflection schematic diagram of the color film.

FIG. 24 is a schematic diagram of 3D polarization display in related art.

FIG. 25 is a schematic diagram of a display substrate with a color filter to achieve 3D polarization display provided by an embodiment of the present disclosure.

FIG. 26 is a schematic structural diagram of the left frame area and the right frame area in the display substrate provided by an embodiment of the present disclosure.

### DETAILED DESCRIPTION

In order to make the purpose, technical solutions and advantages of the embodiments of the present disclosure more clear, the technical solutions of the embodiments of the present disclosure will be clearly and completely described below in conjunction with the drawings of the embodiments of the present disclosure. It should be noted that the sizes and shapes of the figures in the drawings do not reflect true proportions and are only intended to illustrate the present disclosure. And the same or similar reference numbers throughout represent the same or similar elements or elements with the same or similar functions.

Unless otherwise defined, technical terms or scientific terms used in the present disclosure should have ordinary meanings as understood by those of ordinary skill in the art to which the present disclosure belongs. “First”, “second” and similar words used in this disclosure and the claims do not indicate any order, quantity or importance, but are only used to distinguish different components. Words such as “include” or “comprising” mean that the elements or objects before the word include elements or objects after the word and their equivalents, without excluding other elements or objects. “Inside”, “outside”, “up”, “down”, etc. are only used to express relative positional relationships. When the absolute position of the described object changes, the relative positional relationship may also change accordingly.

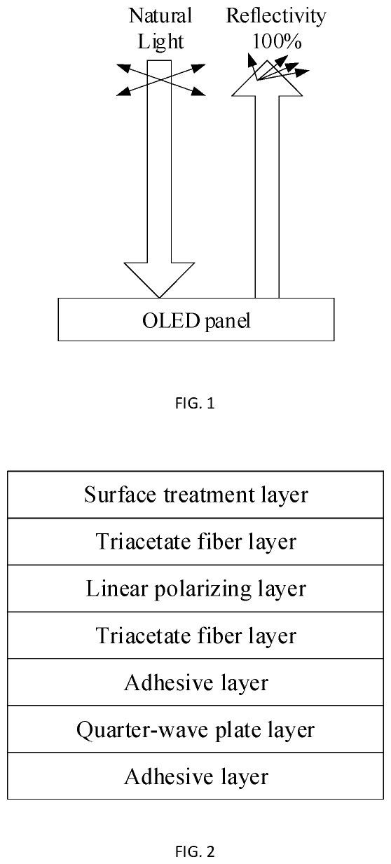

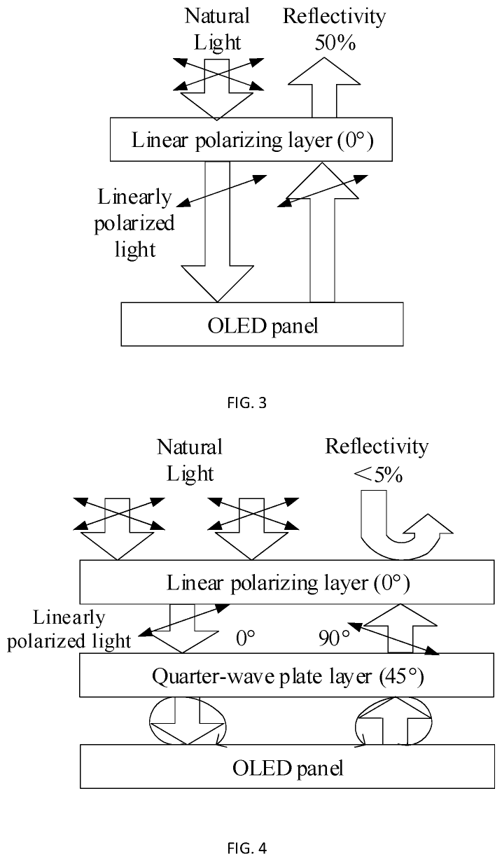

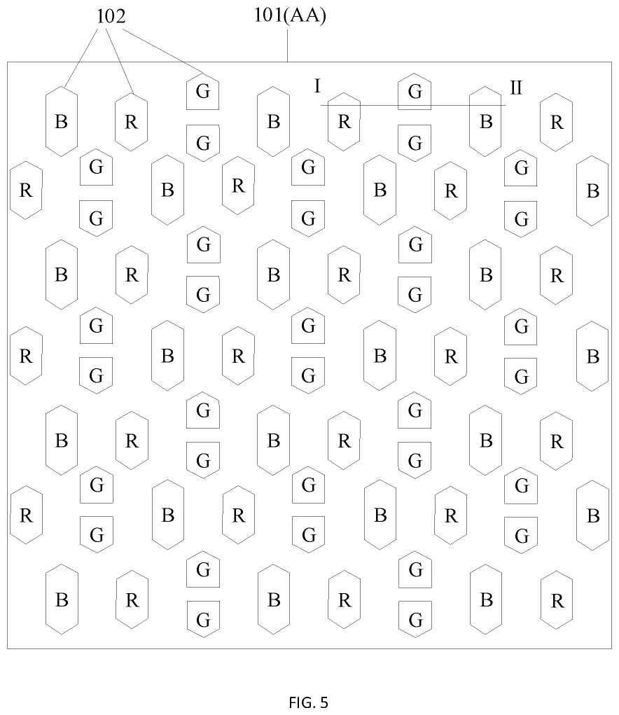

Due to the reflection of external natural light from the cathode and/or anode metal layers in the organic light-emitting display and the metal lines of the backplane drive circuit, the screen contrast and outdoor visibility are low, as shown in FIG. 1. Therefore, in current organic light-emitting displays, the anti-reflection layer (such as circular polarizer) is generally provided to improve this. As shown in FIG. 2, the circular polarizer includes an adhesive layer, a quarter-wave plate layer, an adhesive layer, a triacetate fiber layer, a linear polarizing layer, a triacetate fiber layer and a surface treatment layer arranged in stacked. Here, the main functional layer is the linear polarizing layer and the quarter-wave plate layer, and the anti-reflection principle is shown in FIG. 3 and FIG. 4. However, due to the existence of the linear polarizing layer, the theoretical maximum transmittance of light emitted from the OLED micro-cavity can only reach 50%, while in reality it is generally between 40% and 45%, resulting in a decrease in OLED output efficiency and an increase in power consumption.

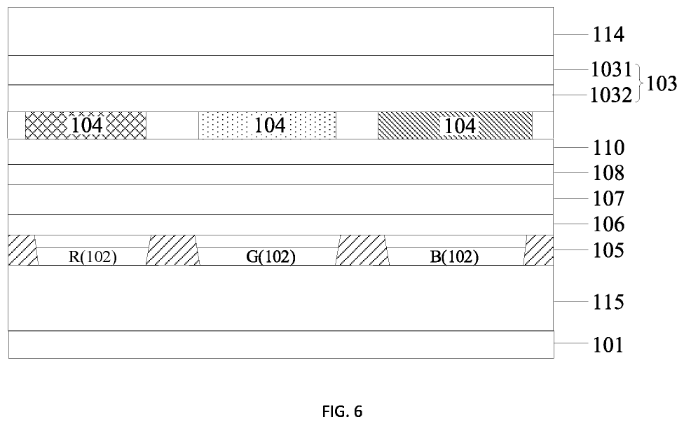

In order to at least improve the above technical problems existing in the related art, embodiments of the present disclosure provide a display substrate, as shown in FIGS. 5 and 6, including:
a base substrate 101;
a plurality of light-emitting devices 102 with a plurality of colors, arranged in an array on the base substrate 101;
an anti-reflection layer 103, arranged on a side of a layer where the light-emitting devices 102 are located facing away from the base substrate 101; where the anti-reflection layer 103 can be a circular polarizer or a color film, where the color film includes a black matrix and a plurality of color resistances separated by the black matrix;
a chiral liquid crystal layer 104, arranged between the layer where the light-emitting devices 102 are located and the anti-reflection layer 103; where an orthographic projection of the chiral liquid crystal layer 104 on the base substrate 101 overlaps with an orthographic projection of at least one color light-emitting device 102 on the base substrate 101; a central reflection wavelength of the chiral liquid crystal layer 104 is approximately same as an emission wavelength of the at least one color light-emitting device 102 overlapping with the chiral liquid crystal layer 104; and a spiral direction of the chiral liquid crystal layer 104 is left-handed or right-handed.

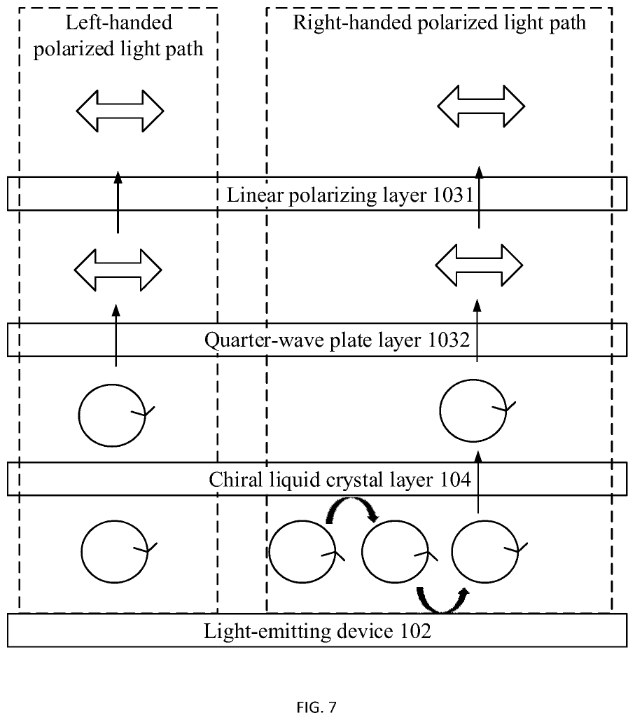

In the above display substrate provided by embodiments of the present disclosure, only when the wavelength of the light is the same as the central reflection wavelength of the chiral liquid crystal layer 104, and the polarization direction of the light is consistent with the spiral direction of the chiral liquid crystal layer 104, the light will be reflected by the chiral liquid crystal layer 104, and the light of any wavelength band whose polarization direction is opposite to the spiral direction of the chiral liquid crystal layer 104 can directly pass through the chiral liquid crystal layer 104. Taking the anti-reflection layer 103 is a circular polarizer and is combined with an area where one light-emitting device 102 is located as an example, as shown in FIG. 7, when the light-emitting device 102 emits light (which is considered to be natural light, it can be decomposed into equal amounts of left-handed polarized light and Right-handed polarized light), assuming that the helical direction of the chiral liquid crystal layer 104 is left-handed, then the right-handed polarized light will be transmitted and transformed into the linearly polarized light through the quarter-wave plate layer 1032 in the circular polarizer, and then the linearly polarized light passes through the linearly polarized layer 1031, and the light emits normally. The left-handed polarized light will be reflected by the chiral liquid crystal layer 104. Since the refractive index of the chiral liquid crystal layer 104 is lower than that of the underlying film layer, there is no half-wave loss. The left-handed polarized light will return to the film layer where the light-emitting device 102 is located. After reflection on the electrode (there is a half-wave loss here), it is transformed into right-handed polarized light, and then passes through the circular polarizer and emits. Therefore, the chiral liquid crystal layer 104 can improve the light extraction efficiency of the light-emitting device 102 whose emission wavelength is the same as the central reflection wavelength of the chiral liquid crystal layer. Based on this, by arranging chiral liquid crystal layers with corresponding central reflection wavelengths above the light-emitting devices 102 of different colors, the overall light extraction efficiency of the display substrate can be maximized and the power consumption can be significantly reduced.

It should be noted that in embodiments provided by the present disclosure, due to the limitations of process conditions or the influence of other factors such as measurement, the term “approximately” may be expressed as completely equivalent, or there may be some deviations, so as long as the “approximately” relationship between relevant features meets the allowable error (such as a 10% fluctuation), it falls within the scope of protection of the present disclosure.

For OLED displays, the long-term burn-in defects may occur after prolonged display. There are mainly differences in brightness and chromaticity between the area where the long-term afterimage appears and the surrounding area. The difference in brightness comes from the brightness attenuation of the luminescent materials of different colors, and the difference in chromaticity comes from the uneven brightness attenuation of the light-emitting devices 102 of different colors. At present, the lifetime of the red light-emitting devices is greater than the lifetime of the green light-emitting devices, and the lifetime of the green light-emitting devices is greater than the lifetime of the blue light-emitting devices. Moreover, many polarizers also have the problem of the red light and the green light transmittance being greater than the blue light transmittance, which leads to yellowing of white images after prolonged display. A common solution to this problem is to increase the opening rate of blue light-emitting devices, so that the opening rate of blue light-emitting devices is greater than the opening rate of green light-emitting devices, and the opening rate of green light-emitting devices is greater than the opening rate of red light-emitting devices, in order to ensure that the lifetime of red light-emitting devices, blue light-emitting devices, and green light-emitting devices is as equal as possible. Especially for applications with long lifetime requirements, such as in vehicles, laptops, etc., the opening rate of blue light-emitting devices is much higher than the opening rate of red light-emitting devices and the opening rate of green light-emitting devices. However, such a design can also bring other disadvantages, such as affecting the backplane wiring and the overall aperture ratio.

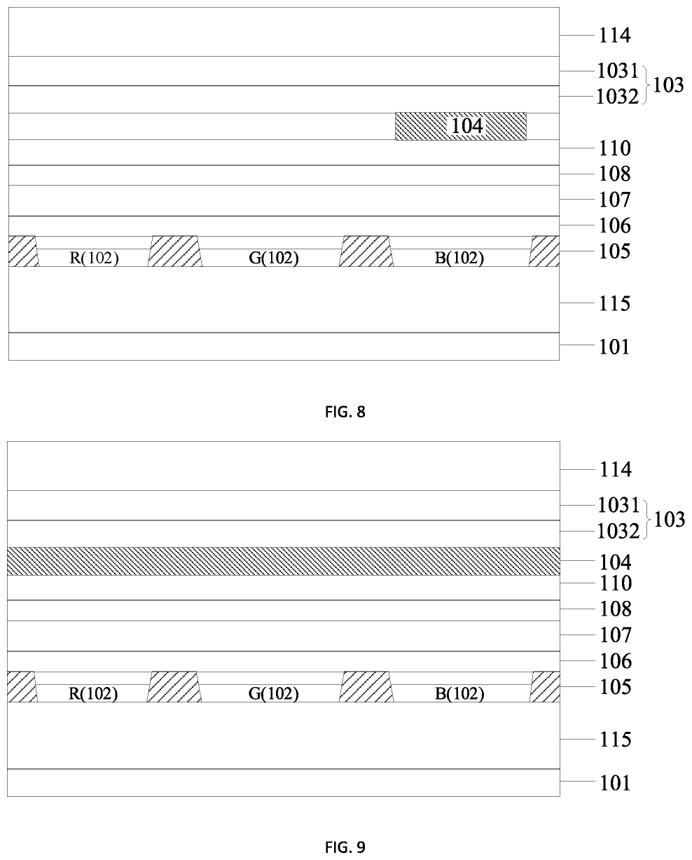

In order to solve the above technical problem of uneven lifetime of light-emitting devices 102 of different colors, in the above-mentioned display substrate provided by the embodiment of the present disclosure, as shown in FIG. 8, the light-emitting devices 102 may include a first light-emitting device R (for example, the red light-emitting device), a second light-emitting device G (for example, the green light-emitting device) and a third light-emitting device B (for example, the blue light-emitting device) with different colors, where the lifetime decay rate of the first light-emitting device R, the lifetime decay rate of the second light-emitting device G and the lifetime decay rate of the third light-emitting device B increase sequentially; the orthographic projection of the chiral liquid crystal layer 104 on the base substrate 101 at least overlaps with the orthographic projection of the third light-emitting device B on the base substrate 101.

By arranging the chiral liquid crystal layer 104 above the third light-emitting device B with the greatest lifetime decay, the light extraction efficiency of the third light-emitting device B can be effectively increased, thereby reducing the current of the third light-emitting device B, thereby improving the third luminescence; improving the aging of the light-emitting material in the third light-emitting device B, prolonging the lifetime of the third light-emitting device B, and making the difference in the lifetime of the first light-emitting device R, the lifetime of the second light-emitting device G, and the lifetime of the third light-emitting device B relatively small or even negligible, effectively improving the uneven lifetime of different colored light-emitting devices 102.

In some embodiments, in the above display substrate provided by the embodiment of the present disclosure, as shown in FIG. 8, the orthographic projection of the chiral liquid crystal layer 104 on the base substrate 101 and the orthographic projection of the third light emitting device B on the base substrate 101 overlap with each other, and the orthographic projection of the chiral liquid crystal layer 104 on the base substrate 101 does not overlap with the orthographic projections of the first light-emitting device R and the orthographic projections of the second light-emitting device G on the base substrate 101. In this case, the chiral liquid crystal layer 104 can be used to increase the lifetime of the third light-emitting device B with the largest life decay rate, reduce the lifetime difference between the third light-emitting device B, the first light-emitting device R, and the second light-emitting device G, and improve the uneven lifetime of the first light-emitting device R, the second light-emitting device G, and the third light-emitting device B.

In some embodiments, in the above-mentioned display substrate provided by the embodiment of the present disclosure, as shown in FIG. 5 and FIG. 9, the orthographic projection of the chiral liquid crystal layer 104 on the base substrate 101 at least completely covers the display area AA of the display substrate, and the central reflection wavelength of the chiral liquid crystal layer 104 is approximately the same as the emission wavelength of the third light-emitting device B. Since the central reflection wavelength of the chiral liquid crystal layer 104 is approximately the same as the emission wavelength of the third light-emitting device B, the chiral liquid crystal layer 104 only reflects the polarized light in the third light-emitting device B that has the same spiral direction as the spiral direction of the chiral liquid crystal layer 104; and the polarized light in the direction opposite to the spiral direction of the chiral liquid crystal layer 104 in the light of the first light-emitting device R, the second light-emitting device G and the third light-emitting device B can directly pass through without being affected. In terms of panel optics, it is reflected that the light extraction efficiency of the third light-emitting device B is increased, which improves the lifetime of the third light-emitting device B. Moreover, since the chiral liquid crystal layer 104 is arranged on the entire surface, compared with the scheme shown in FIG. 8, which only arranges the chiral liquid crystal layer 104 above the third light-emitting device B, a mask process can be omitted, and the process is simpler.

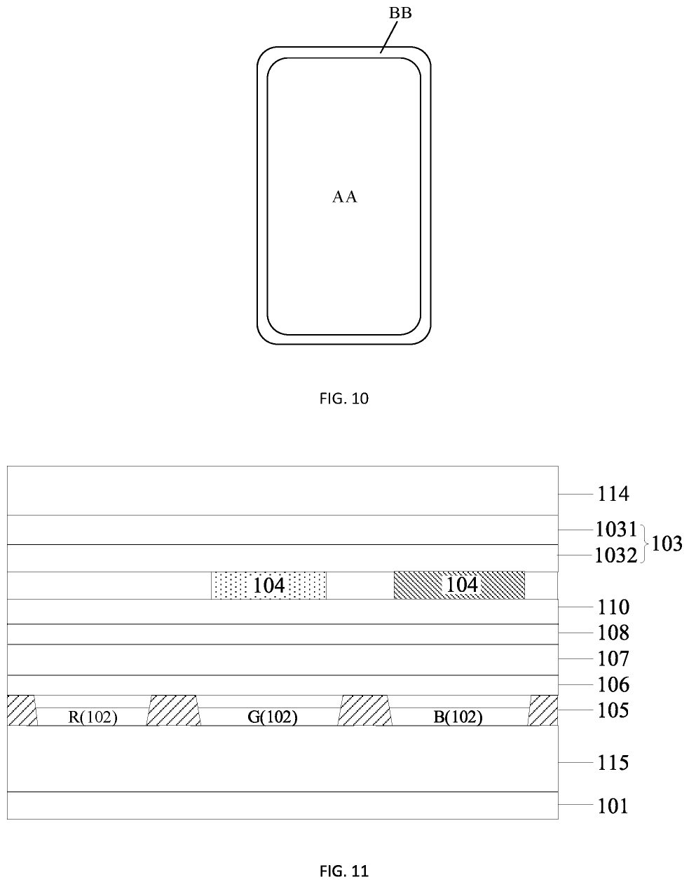

It should be noted that in some embodiments, as shown in FIG. 5, when the display substrate provided by the embodiments of the present disclosure is a full screen, the area of the display area AA is basically the same as the surface of the base substrate 101 facing the light emitting device 102. So that, the orthographic projection of the chiral liquid crystal layer 104 on the base substrate 101 at least completely covers the display area AA of the display substrate, which is equivalent to the chiral liquid crystal layer 104 being arranged on the entire surface. In other embodiments, as shown in FIG. 10, the display substrate provided by the embodiments of the present disclosure may include a display area AA and a frame area BB, then the orthographic projection of the chiral liquid crystal layer 104 on the base substrate 101 at least completely covers the display area AA of the display substrate can include the following two solutions: first, the chiral liquid crystal layer 104 is only arranged in the display area AA; second, the chiral liquid crystal layer 104 is arranged in both the display area AA and the frame area BB, that is, the chiral liquid crystal layer 104 is arranged on the entire surface.

In some embodiments, in the above-mentioned display substrate provided by the embodiments of the present disclosure, in order to further balance the lifetime of the light-emitting devices 102 of different colors, as shown in FIG. 11, the orthographic projection of the chiral liquid crystal layer 104 on the base substrate 101 and the orthographic projections of the second light-emitting device G on the base substrate 101 and the orthographic projections of the third light-emitting device B on the base substrate 101 overlap with each other, and the orthographic projection of the chiral liquid crystal layer 104 on the base substrate 101 and the orthographic projection of the first light-emitting device R on the base substrate 101 do not overlap with each other. The central reflection wavelength of the chiral liquid crystal layer 104 overlapped with the second light-emitting device G is approximately equal to the emission wavelength of the second light-emitting device G, so that the light extraction efficiency and lifetime of the second light-emitting device G can be improve by the arrangement of the chiral liquid crystal layer 104. The central reflection wavelength of the chiral liquid crystal layer 104 overlapped with the third light-emitting device B is approximately equal to the emission wavelength of the third light-emitting device B, so that the light extraction efficiency and lifetime of the third light-emitting device B can be improve by the arrangement of the chiral liquid crystal layer 104.

In some embodiments, the process flow of the chiral liquid crystal layer 104 may be: coating of alignment layer→pre-curing→main curing→alignment→post-drying→coating of chiral liquid crystal material→low-temperature drying of solvent→ultraviolet (UV) curing. Here, the material of the alignment layer can be polyimide (PI), and the material can be cured to form a film under low temperature conditions. Specifically, the temperature can be limited to below 95° C. In addition, the chiral liquid crystal layer 104 on the second light-emitting device G and the third light-emitting device B can be produced through two patterning processes. For example, after the chiral liquid crystal layer 104 on the second light-emitting device G is UV-cured, the chiral liquid crystal layer 104 on the third light-emitting device B can be formed (here it only includes “coating chiral liquid crystal material→low-temperature drying of solvent→UV curing” three steps), and at the same time, photolithography (PR) glue can be used to protect the previously produced chiral liquid crystal layer 104 on the second light-emitting device G.

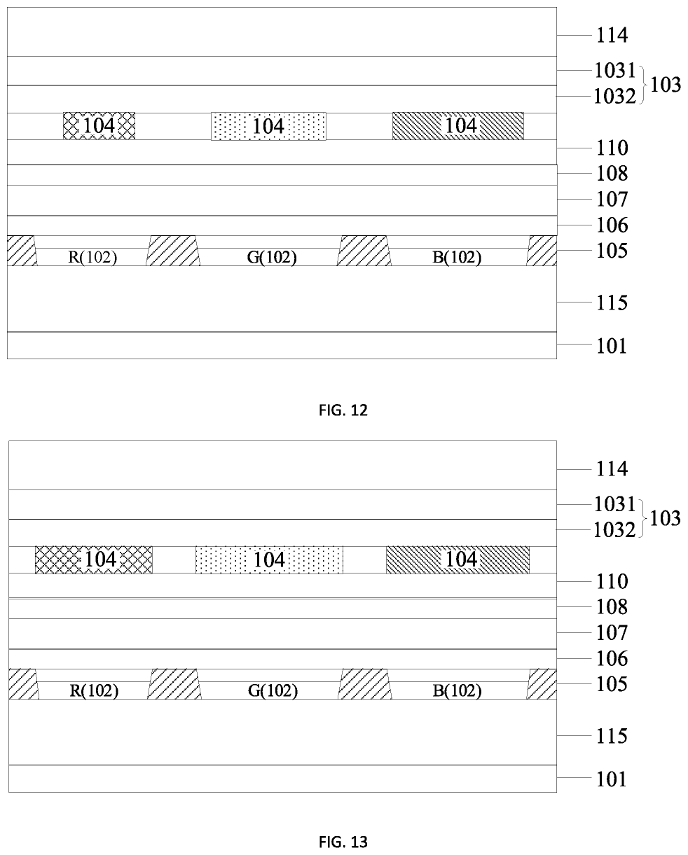

In some embodiments, in the above-mentioned display substrate provided by the embodiments of the present disclosure, as shown in FIG. 12, the orthographic projection of the chiral liquid crystal layer 104 on the base substrate 101 overlaps with the orthographic projections of all the light-emitting devices 102 on the base substrate 101. The central reflection wavelength of the chiral liquid crystal layer 104 overlapped with the first light-emitting device R is approximately equal to the emission wavelength of the first light-emitting device R; the central reflection wavelength of the chiral liquid crystal layer 104 overlapped with the second light-emitting device G is approximately equal to the emission wavelength of the second light-emitting device G; and the central reflection wavelength of the chiral liquid crystal layer 104 overlapped with the third light-emitting device B is approximately equal to the emission wavelength of the third light-emitting device B. In this way, the light extraction efficiency of the light-emitting devices 102 with different colors can be improved by arranging the chiral liquid crystal layers 104 with different central reflection wavelengths. In some embodiments, the chiral liquid crystal layers on the first light-emitting device R, the second light-emitting device G and the third light-emitting device B can be produced through three patterning processes, respectively.

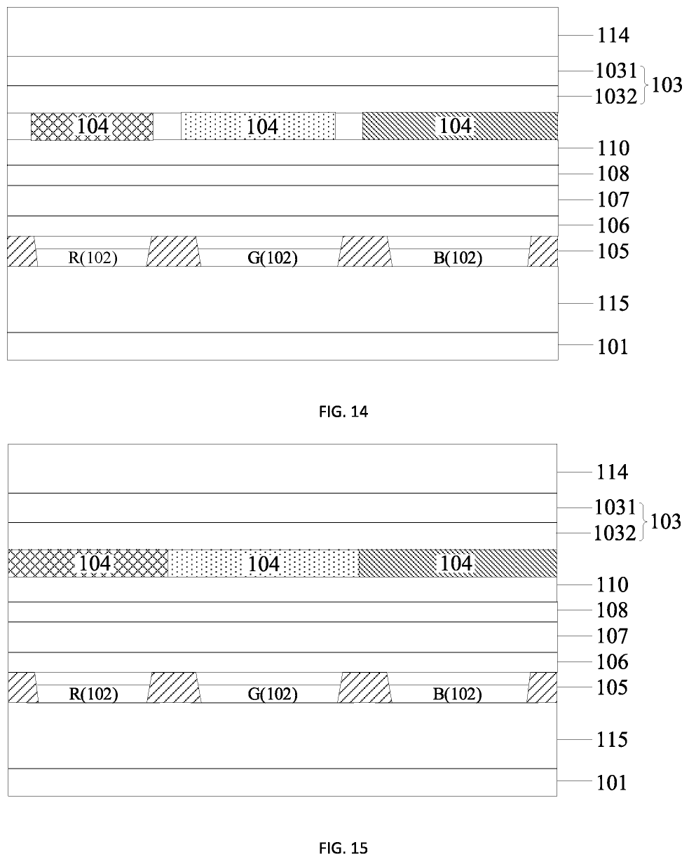

In some embodiments, the above-mentioned display substrate provided by the embodiments of the present disclosure, as shown in FIGS. 8, 11 and 12, may also include: a pixel definition arranged on the side of the chiral liquid crystal layer 104 facing the base substrate 101, where the pixel definition layer 105 includes a plurality of pixel openings (equivalent to the effective light-emitting area of the light-emitting device 102), and the light-emitting devices 102 are located in the pixel openings; the orthographic projection of the chiral liquid crystal layer 104 on the base substrate 101 can be located within the orthographic projection of the pixel opening, where the light-emitting device 102 overlapped with the chiral liquid crystal layer 104 is located, on the base substrate 101. That is, the ratio of an area of the orthographic projection of the chiral liquid crystal layer 104 to an area of the orthographic projection of the pixel opening below the chiral liquid crystal layer 104 is less than 1. Alternatively, as shown in FIG. 13, the orthographic projection of the chiral liquid crystal layer 104 on the base substrate 101 approximately coincides with the orthographic projection of the pixel opening, where the light-emitting device 102 overlapped with the chiral liquid crystal layer 104 is located, on the base substrate 101. The ratio of an area of the orthographic projection of the chiral liquid crystal layer 104 to an area of the pixel opening below the chiral liquid crystal layer 104 is approximately equal to 1, which effectively improves the light extraction efficiency of the light-emitting device 102 at the front viewing angle. In some embodiments, as shown in FIGS. 14 and 15, the orthographic projection of the chiral liquid crystal layer 104 on the base substrate 101 covers and is larger than an orthographic projection of the pixel opening, where the light-emitting device 102 overlapped with the chiral liquid crystal layer 104 is located, on the base substrate 101. That is, the ratio of an area of the orthographic projection of the chiral liquid crystal layer 104 to an area of the pixel opening below the chiral liquid crystal layer 104 is greater than 1. Specifically, there is a gap between the chiral liquid crystal layers 104 on the light-emitting devices 102 with different colors in FIG. 12, the chiral liquid crystal layers 104 on the light-emitting devices 102 with different colors are in contact with each other in FIG. 15, to simultaneously improve the light extraction efficiency of the light-emitting devices 102 at both front viewing angle and oblique viewing angle. It should be noted that, the area, the chiral liquid crystal layers 104 on the light-emitting devices 102 with different colors exceeding the pixel openings (that is, the overlapping area with the pixel defining layer 105) below the chiral liquid crystal layers 104, can be the same or different in size, and is not limited here.

In some embodiments, in the above-mentioned display substrate provided by embodiments of the present disclosure, as shown in FIGS. 12 and 14, a percentage of an area of the orthographic projection of the chiral liquid crystal layer 104 on the base substrate 101 to an area of the orthographic projection of the pixel opening overlapped with the chiral liquid crystal layer 104 on the base substrate 101, is negatively correlated with a lifetime decay rate of the light-emitting device 102 overlapped with chiral liquid crystal layer 104. The larger the overlap area between the chiral liquid crystal layer 104 and the pixel opening below the chiral liquid crystal layer 104, the more obvious the effect of improving the light extraction efficiency of the light emitting device 102 at the pixel opening will be. Therefore, the above arrangement can improve the light extraction efficiency of the light emitting device 102 of different colors, while the lifetime of the light-emitting devices 102 of different colors can also be made almost the same.

In some embodiments, since the lifetime decay rates of the first light-emitting device R, the second light-emitting device G and the third light-emitting device B increase in sequence; the ratio of the orthographic projection area of the chiral liquid crystal layer 104 above the second light-emitting device G to the pixel opening where the second light-emitting device G is located, is greater than the ratio of the orthographic projection area of the chiral liquid crystal layer 104 above the first light-emitting device R to the pixel opening where the first light-emitting device R is located; and the ratio of the orthographic projection area of the chiral liquid crystal layer 104 above the second light-emitting device G to the pixel opening where the second light-emitting device G is located, is smaller than the ratio of the orthographic projection area of the chiral liquid crystal layer 104 above the third light-emitting device B to the pixel opening where the third light-emitting device B is located. In some embodiments, the ratio of the orthographic projection area of the chiral liquid crystal layer 104 above the third light-emitting device B to the pixel opening where the third light-emitting device B is located ranges from 95% to 100%; the ratio of the orthographic projection area of the chiral liquid crystal layer 104 above the second light-emitting device G to the pixel opening where the second light-emitting device G is located ranges from 85% to 95%; the ratio of the orthographic projection area of the chiral liquid crystal layer 104 above the first light-emitting device R to the pixel opening where the first light-emitting device R is located ranges from 70% to 85%.

In some embodiments, in the above display substrate provided by the embodiments of the present disclosure, the central reflection wavelength of the chiral liquid crystal layer 104 satisfies the following relationship: λₘₐₓ=n_{avg}*P, Δλ=Δn*P; where λₘₐₓ is the peak value of the central reflection wavelength of the chiral liquid crystal layer 104, n_{avg} is the average refractive index of the chiral liquid crystal layer 104, P is the helical pitch of the chiral liquid crystal layer 104, Δλ is the spectrum width of the central reflection wavelength of the chiral liquid crystal layer 104, Δn is the difference between the ordinary light refractive index and the extraordinary light refractive index of the chiral liquid crystal layer 104. Therefore, the center reflection wavelength of the chiral liquid crystal layer 104 above the light-emitting device 102 of different colors can be obtained by adjusting the average refractive index and/or helical pitch of the chiral liquid crystal layer 104 above the light-emitting device 102 of different colors. That is, the average refractive index and/or the helical pitch of the chiral liquid crystal layer 104 overlapped with the light-emitting devices 102 of different colors are different.

In some embodiments, the average refractive index n_{avg} of the chiral liquid crystal layer 104 is greater than or equal to 1.2 and less than or equal to 1.8, the helical pitch P of the chiral liquid crystal layer 104 is greater than 0 μm and less than or equal to 3 μm, and the difference between the ordinary light refractive index and the extraordinary light refractive index of the chiral liquid crystal layer 104 Δn is greater than 0 and less than or equal to 0.2. In some embodiments, the central reflection wavelength of the chiral liquid crystal layer 104 above the first light-emitting device R (e.g., the red light-emitting device 102) may be (620±30) nm, and the center reflection wavelength of the chiral liquid crystal layer 104 above the second light-emitting device G (e.g., the green light-emitting device 102) may be (530±30) nm, and the central reflection wavelength of the chiral liquid crystal layer 104 above the third light-emitting device B (e.g., the blue light-emitting device 102) may be (450±30) nm.

In some embodiments, in the above display substrate provided by the embodiments of the present disclosure, the spiral directions of the chiral liquid crystal layer 104 overlapped with the light-emitting devices 102 of different colors are the same. In other words, the spiral directions of the chiral liquid crystal layer 104 above the light-emitting device 102 of different colors can all be left-handed, or the spiral directions of the chiral liquid crystal layer 104 above the light-emitting device 102 of different colors can all be right-handed.

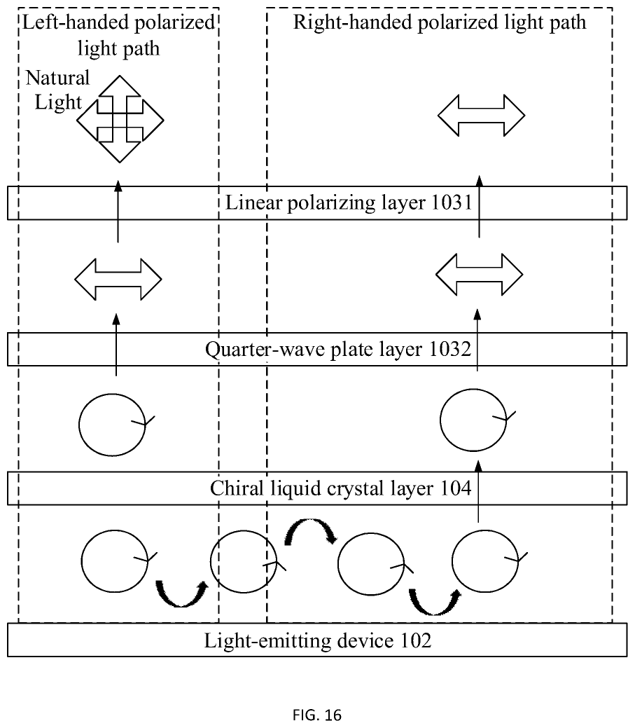

In the present disclosure, although the chiral liquid crystal layer 104 can improve the light extraction efficiency of the light-emitting device, when the anti-reflection layer 103 is a circular polarizer, the chiral liquid crystal layer 104 will have negative effects on the anti-reflection of the circular polarizer. As shown in FIG. 16, after the external natural light passes through the linear polarizing layer 1031 in the circular polarizer, half of the light is absorbed and converted into linearly polarized light. After the polarization direction is changed by the metal interface, this part of the light cannot pass through the chiral liquid crystal layer 104, so this part of the light reflected back and forth between the chiral liquid crystal layer 104 and the metal electrode, and finally penetrates the circular polarizer and emits. This will cause the reflectivity of the display to increase, affecting the display effect.

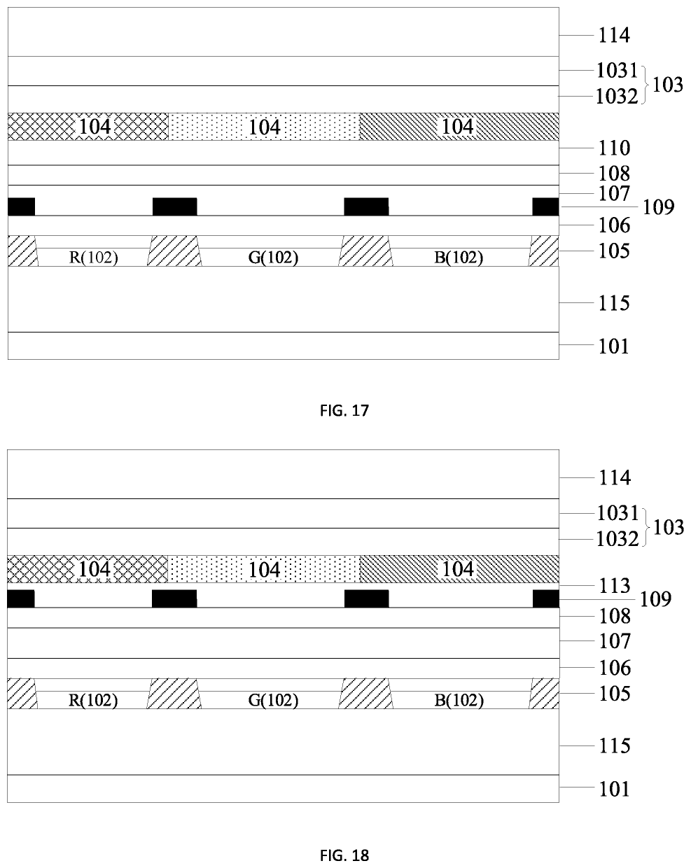

Based on this, in order to improve the anti-reflection effect, the above-mentioned display substrate provided by the embodiments of the present disclosure, as shown in FIG. 17, may also include: a light-absorbing layer 109 arranged between the layer where the plurality of light-emitting devices 102 is located and the chiral liquid crystal layer 104. The orthographic projection of the light-absorbing layer 109 on the base substrate 101 approximately coincides with the orthographic projection of the pixel definition layer 105 on the base substrate 101. The light-absorbing layer 109 is used to absorb external light incident into the interior of the display substrate, thereby avoiding its reflected back to the outside of the display substrate by the metal electrode. In some embodiments, the light absorbing layer 109 may be made of black matrix material.

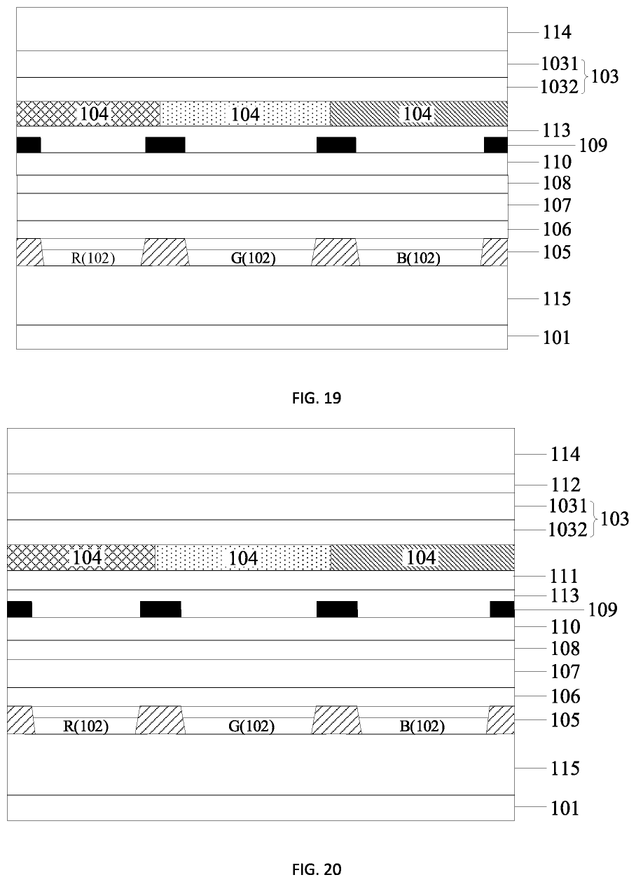

In some embodiments, the above-mentioned display substrate provided by the embodiments of the present disclosure, as shown in FIGS. 17 and 18, may further include: a first inorganic encapsulation layer 106, an organic encapsulation layer 107 and a second inorganic encapsulation layer 108 arranged in sequence on a side of the light-emitting device 102 facing the chiral liquid crystal layer 104; the light-absorbing layer 109 is arranged between the first inorganic encapsulating layer 106 and the organic encapsulating layer 107, or the light-absorbing layer 109 is arranged between the second inorganic encapsulating layer 108 and the chiral liquid crystal layer 104. In some embodiments, as shown in FIG. 19, the display substrate may further include a touch functional layer 110 arranged between the layer where the light-emitting devices 102 are located and the chiral liquid crystal layer 104; and the light-absorbing layer 109 is arranged between the touch function layer 110 and the chiral liquid crystal layer 104. It should be understood that as long as the light-absorbing layer 109 is arranged between the layer where the plurality of light-emitting devices 102 are located and the chiral liquid crystal layer 104, it is not limited to the film layer positions shown in FIGS. 17 to 19.

In some embodiments, the above-mentioned display substrate provided by the embodiments of the present disclosure, as shown in FIG. 20, may also include a first adhesive layer 111 disposed in contact with the surface of the chiral liquid crystal layer 104 facing the base substrate 101, and a second adhesive layer 112 disposed in contact with the surface of the circular polarizer facing away from the base substrate 101; the chiral liquid crystal layer 104 is fixed to the first flat layer 113 used to reduce the gap through the first adhesive layer 111; the circular polarizer is fixed to the cover plate 114 through the second adhesive layer 112. In the case where the first adhesive layer 111 is used to fix the chiral liquid crystal layer 104, the chiral liquid crystal layer 104 can be prepared on PET, PI or other substrate materials. Of course, in some embodiments, as shown in FIG. 18, the chiral liquid crystal layer 104 can also be directly formed on the first flat layer 113, and the layers of the circular polarizer can be directly formed on the chiral liquid crystal layer 104. It is not limited here.

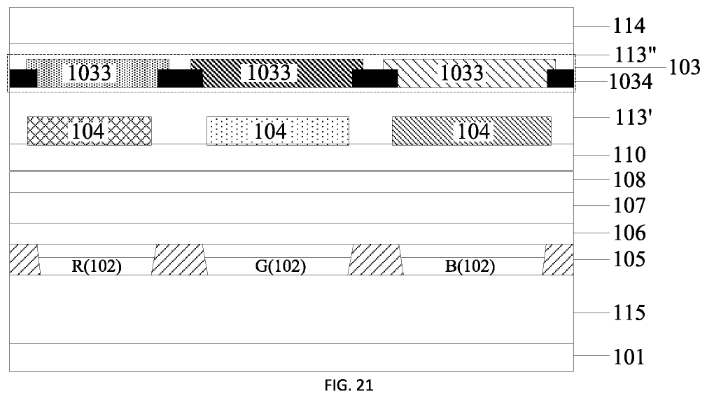

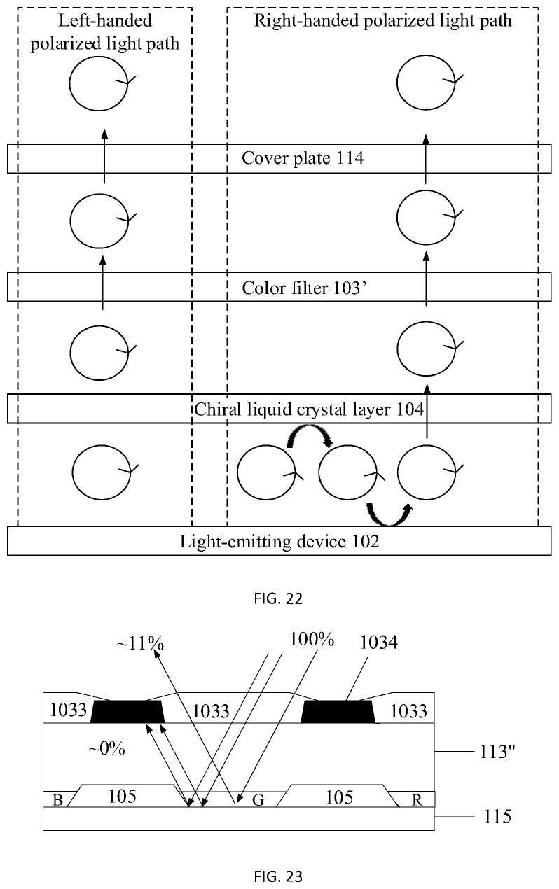

In some embodiments, in the above-mentioned display substrate provided by the embodiments of the present disclosure, as shown in FIGS. 21 and 22, the anti-reflection layer 103 may be a color filter 103′, and the color filter 103′ includes a plurality of color resistors 1033 and the black matrix 1034, in which the plurality of color resistors 1033 are separated by the black matrix 1034. The orthographic projection of the color resistor 1033 on the base substrate 101 approximately coincides with the orthographic projection of the pixel opening on the base substrate 101. The orthographic projection on 101 of the black matrix 1034 on the base substrate approximately coincides with the orthographic projection of the pixel defining layer 105 on the base substrate 101. In order to improve the color purity, it is preferred that the orthographic projection of the color resistor 1033 on the base substrate 101 is slightly larger than the orthographic projection of the pixel opening on the base substrate 101. Correspondingly, the orthographic projection of the black matrix 1034 on the base substrate 101 is slightly smaller than the orthographic projection of the pixel defining layer 105 on the base substrate 101.

In some embodiments, an area where one light-emitting device 102 is located is used as an example for illustration. As shown in FIG. 22, when the light-emitting device 102 emits light (which is considered to be natural light, it can be decomposed into equal amounts of left-handed polarized light and Right-handed polarized light), it is assumed that the chiral liquid crystal molecules in the chiral liquid crystal layer 104 are left-handed, then right-handed polarized light will be transmitted and exit normally through color resistance 1033. The left-handed polarized light will be reflected by the chiral liquid crystal layer 104. Since the refractive index of the chiral liquid crystal layer 104 is lower than that of the underlying film layer, there is no half-wave loss. The left-handed polarized light will return to the film layer where the light-emitting device 102 is located. After reflection on the metal electrode (there is a half-wave loss here), it is transformed into right-handed polarized light, and then emits with the same way. Therefore, the chiral liquid crystal layer 104 can improve the light extraction efficiency of the light-emitting device 102 whose emission wavelength is the same as the central reflection wavelength of the chiral liquid crystal layer. Based on this, by arranging chiral liquid crystal layers with corresponding central reflection wavelengths above the light-emitting devices 102 of different colors, the overall light extraction efficiency of the display substrate can be maximized and the power consumption can be significantly reduced. In addition, since the color resistor 1033, the first flat layer 113 and the cover plate 114 are all isotropic materials, the polarization state of the light will not be changed after passing through these layers.

In some embodiments, the color resistor 1033 may include a red color resistor located above the red light emitting device (R), a green light color resistor located above the green light emitting device (G), and a blue light color resistor located above the blue light emitting device (B).

In addition, as shown in FIG. 23, the transmittance of the circular polarizer is generally between 40% and 45%. The color filter 103′ on encapsulation (COE) made of color resistance 1033 and black matrix 1034 can achieve a transmittance of 60% according to simulation, which is greatly improved compared to circularly polarized films. Therefore, the COE structure of the present disclosure combined with the chiral liquid crystal layer 104 can effectively improve the light extraction efficiency and reduce the reflection of ambient light, which is very beneficial to 3D screens with high brightness requirements.

The existing 3D display methods are mainly divided into two types: the glasses type and the naked eye type. The glasses type utilizes polarized 3D technology, which has the smallest color loss, the color display is closest to the original value, and the 3D display effect is also more prominent, providing a realistic three-dimensional feeling. The existing polarized 3D technology is to install linearly polarizing plates with absorption axes perpendicular to each other on the left and right glasses, respectively receiving linearly polarized light in two vibration directions, thereby realizing 3D display in the human brain.

However, there is an obvious problem in using linearly polarized light to achieve 3D display. When the sightlines of the left and right eyes are not on the same horizontal line, the crosstalk will occur between the left and right frames, affecting the stereoscopic image effect. In actual movie viewing, it is difficult for movie viewers to maintain a completely upright position with their heads for a long time. Therefore, the use of linearly polarized 3D technology cannot meet the demand for comfortable viewing.

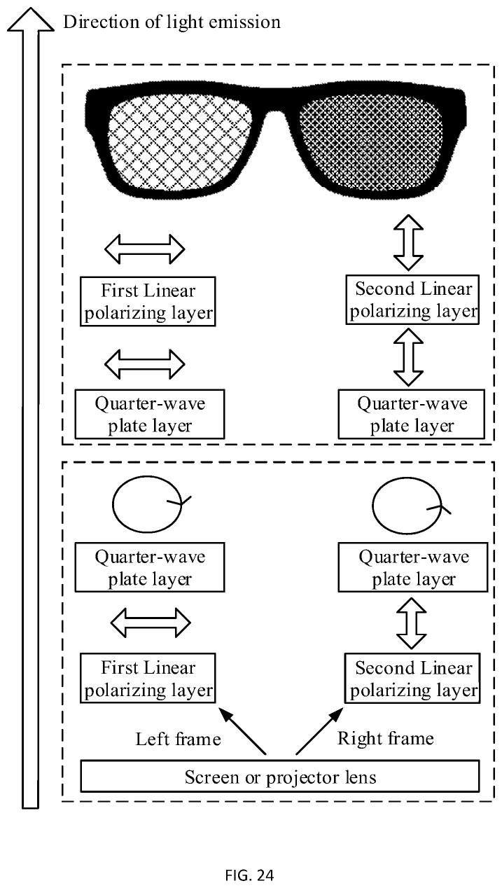

The current improvement plan is to use circular polarization 3D technology. This technology adds a circular polarizer on the screen or in front of the projector lens, so that the light emitted by the screen or projector is circularly polarized light. The left and right frames correspond to either left-handed polarized light or right-handed polarized light, respectively. In addition, the circular polarizers are also attached to the left and right glasses to correspond to the two types of circularly polarized light. The specific structure is shown in FIG. 24.

The advantage of this arrangement is that since the vibration direction of the linearly polarized light output by the quarter-wave plate layer on the glasses is fixed relative to the optical axis direction of the quarter-wave plate layer, it is not affected by the deviation of the glasses position. That is, changes in posture (relative angle to the screen) and position during the viewing process will not affect the 3D effect.

However, this principle is difficult to apply to OLED displays. First of all, OLED needs to attach a circular polarizer due to the requirement of reducing reflection. The structure and the principle of reducing reflection are shown in FIG. 4. Since the linear polarizer is located on the top layer, the light emitted by OLED is ultimately linearly polarized, and this process causes at least half of the light emitted by OLED to be absorbed. If, on this basis, a quarter-wave plate layer is attached to the screen to convert linearly polarized light into circularly polarized light for 3D display, the brightness of the left and right frames will be lost by half, resulting in insufficient brightness during final viewing or high display power consumption.

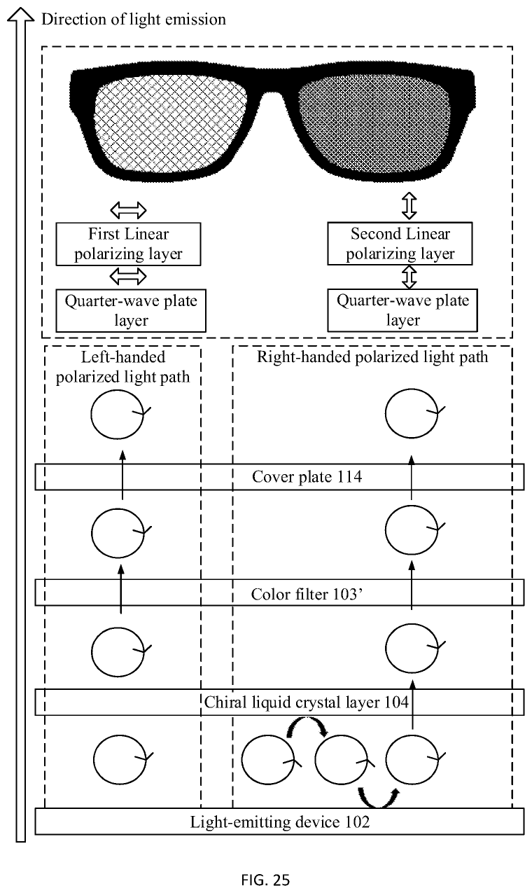

As shown in FIG. 25, the light emitted by each light-emitting device 102 in the present disclosure (including left-handed polarized light and right-handed polarized light) can all pass through the chiral liquid crystal layer 104 and be emitted as left-handed polarized light or right-handed polarized light, to improve the light extraction efficiency. Since the color resistor 1033, the first flat layer 113 and the cover plate 114 are all isotropic materials, the polarization state of the light will not be changed after passing through these layers. Therefore, it can be combined with the circular polarizers attached to the left and right glasses to achieve a 3D effect, and changes in posture (relative angle to the screen) and position during the viewing process will not affect the 3D effect.

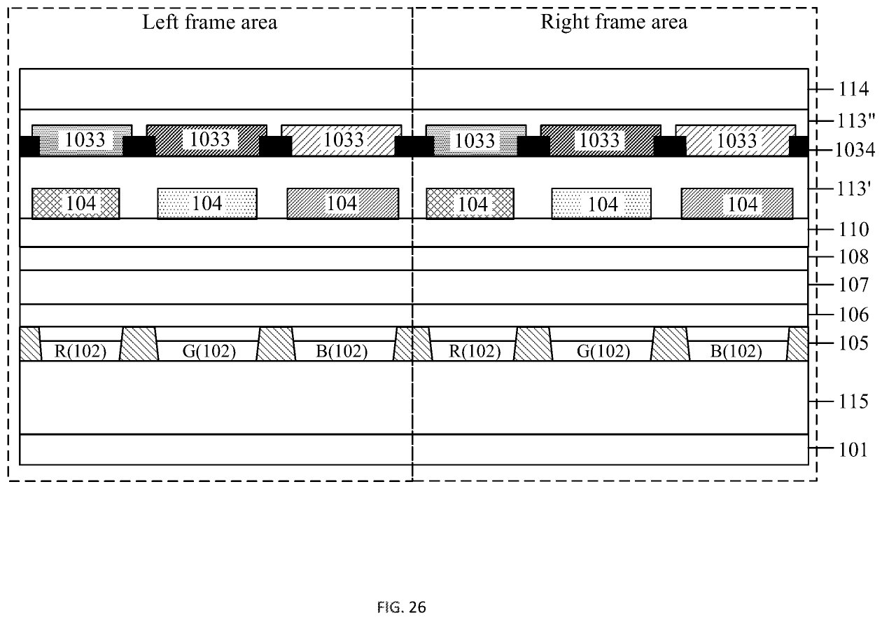

In some embodiments, in the above display substrate provided by the embodiments of the present disclosure, as shown in FIG. 26, the display area of the display substrate includes a left frame area and a right frame area, where a spiral direction of the chiral liquid crystal layer 104 in the left frame area is opposite with a spiral direction of the chiral liquid crystal layer 104 in the right frame area; and a total number of the light-emitting devices 102 in the left frame area is equal to a total number of the light-emitting devices 102 in the right frame area, to achieve a 3D effect while improving the viewing experience.

In some embodiments, the spiral direction of the chiral liquid crystal layer 104 in the left frame area can be left-handed, so that the emitted light of the light-emitting device 102 is converted into right-handed polarized light after passing through the chiral liquid crystal layer 104. The spiral direction of the chiral liquid crystal layer 104 in the right frame area can be right-handed, so that the emitted light of the light-emitting device 102 is converted into left-handed polarized light after passing through the chiral liquid crystal layer 104. Or, the spiral direction of the chiral liquid crystal layer 104 in the right frame area can be left-handed, so that the emitted light of the light-emitting device 102 is converted into right-handed polarized light after passing through the chiral liquid crystal layer 104. The spiral direction of the chiral liquid crystal layer 104 in the left frame area can be right-handed, so that the emitted light from the light-emitting device 102 is converted into left-handed polarized light after passing through the chiral liquid crystal layer 104.

In some embodiments, in the above display substrate provided by the embodiments of the present disclosure, as shown in FIG. 26, the left frame area and the right frame area are areas on both sides of a column direction symmetry axis of the display area. Alternatively, the left frame area and the right frame area are alternately arranged in a row direction and/or a column direction, and each of the left frame area or each of the right frame area includes at least one light emitting device 102. Of course, during specific implementation, other arrangement methods of the left frame area and the right frame area known to those skilled in the art may also be adopted, which are not limited here.

In some embodiments, in the above-mentioned display substrate provided by the embodiments of the present disclosure, the center of the orthographic projection of the chiral liquid crystal layer 104 on the base substrate 101 approximately coincides with the center of the orthographic projection of the light-emitting devices 102 overlapped with the chiral liquid crystal layer 104 on the base substrate 101, so that the viewing angle brightness attenuation and color shift remain consistent at all angles of view.

In the present disclosure, the center of the orthographic projection of the chiral liquid crystal layer 104 may be a central area that deviates from the geometric center of the orthographic projection of the chiral liquid crystal layer 104 by 0 μm to 1 μm. The center of the orthographic projection of the light-emitting device 102 may be a central area that deviates from the geometric center of the orthographic projection of the light-emitting device 102 by 0 μm to 1 μm.

In some embodiments, in the above display substrate provided by the embodiments of the present disclosure, as shown in FIG. 21, in order to reduce the gap, a second flat layer 113′ can be arranged to cover the chiral liquid crystal layer 104. In addition, in order to reduce the gap, a third flat layer 113″ can also be arranged above the color resistor 1033. Generally, the display substrate may also include a driving circuit layer 115 to drive the light emitting device 102 to emit light. Other essential components of the display substrate are understood by those of ordinary skill in the art, and will not be described in detail here, nor should they be used to limit the present disclosure.

Based on the same inventive concept, embodiments of the disclosure provide a display device, including the above display substrate provided by embodiments of the disclosure. Since the principle of the display device to solve the problem is similar to the principle of the above-mentioned display substrate to solve the problem, therefore, the implementation of the display device provided by the embodiments of the present disclosure can be referred to the implementation of the above-mentioned display substrate provided by the embodiments of the present disclosure, and the duplicate content will not be repeated here.

In some embodiments, the display device can be: a mobile phone, a tablet computer, a television, a monitor, a notebook computer, a digital photo frame, a navigator, a smart watch, a fitness wristband, a personal digital assistant, or any other product or component with a display function. The display device includes but is not limited to: radio frequency unit, network module, audio output and input unit, sensor, display unit, user input unit, interface unit, memory, processor, power supply and other components. In addition, those skilled in the art can understand that the above structure does not constitute a limitation on the above display device provided by the embodiments of the present disclosure. In other words, the above display device provided by the embodiments of the present disclosure may include more or less of components, or combinations of certain components, or different arrangements of components.

Although the preferred embodiments of the present disclosure have been described, those skilled in the art can make various modifications and variations to embodiments of the present disclosure without departing from the spirit and scope of embodiments of the present disclosure. In this way, if the modifications and variations of embodiments of the present disclosure fall within the scope of the claims of the present disclosure and their equivalent technologies, the present disclosure is also intended to include these modifications and variations.

1. A display substrate, comprising:
a base substrate;
a plurality of light-emitting devices with a plurality of colors, arranged in an array on the base substrate;
an anti-reflection layer, arranged on a side of a layer where the light-emitting devices are located facing away from the base substrate; and
a chiral liquid crystal layer, arranged between the layer where the light-emitting devices are located and the anti-reflection layer;
wherein an orthographic projection of the chiral liquid crystal layer on the base substrate overlaps with an orthographic projection of at least one color light-emitting device on the base substrate;
a central reflection wavelength of the chiral liquid crystal layer is approximately same as an emission wavelength of the at least one color light-emitting device overlapping with the chiral liquid crystal layer; and
a spiral direction of the chiral liquid crystal layer is left-handed or right-handed.

2. The display substrate according to claim 1, wherein the plurality of light-emitting devices comprise a first light-emitting device, a second light-emitting device and a third light-emitting device with different colors;
wherein a lifetime decay rate of the first light-emitting device, a lifetime decay rate of the second light-emitting device and a lifetime decay rate of the third light-emitting device increase sequentially; and
the orthographic projection of the chiral liquid crystal layer on the base substrate at least overlaps with an orthographic projection of the third light-emitting device on the base substrate.

3. The display substrate according to claim 2, wherein the orthographic projection of the chiral liquid crystal layer on the base substrate and the orthographic projection of the third light-emitting device on the base substrate overlap with each other; and
the orthographic projection of the chiral liquid crystal layer on the base substrate does not overlap with an orthographic projection of the first light-emitting device on the base substrate and an orthographic projection of the second light-emitting device on the base substrate.

4. The display substrate according to claim 2, wherein the orthographic projection of the chiral liquid crystal layer on the base substrate at least completely covers a display area of the display substrate; and
the central reflection wavelength of the chiral liquid crystal layer is approximately same as an emission wavelength of the third light-emitting device.

5. The display substrate according to claim 2, wherein the orthographic projection of the chiral liquid crystal layer on the base substrate overlaps with an orthographic projection of the second light-emitting device on the base substrate and an orthographic projection of the third light-emitting device on the base substrate; and the orthographic projection of the chiral liquid crystal layer on the base substrate and an orthographic projection of the first light-emitting device on the base substrate do not overlap with each other;
the central reflection wavelength of the chiral liquid crystal layer overlapped with the second light-emitting device is approximately equal to an emission wavelength of the second light-emitting device; and
the central reflection wavelength of the chiral liquid crystal layer overlapped with the third light-emitting device is approximately equal to an emission wavelength of the third light-emitting device.

6. The display substrate according to claim 2, wherein the orthographic projection of the chiral liquid crystal layer on the base substrate overlaps with orthographic projections of all the light-emitting devices on the base substrate;
the central reflection wavelength of the chiral liquid crystal layer overlapped with the first light-emitting device is approximately equal to an emission wavelength of the first light-emitting device;
the central reflection wavelength of the chiral liquid crystal layer overlapped with the second light-emitting device is approximately equal to an emission wavelength of the second light-emitting device; and
the central reflection wavelength of the chiral liquid crystal layer overlapped with the third light-emitting device is approximately equal to an emission wavelength of the third light-emitting device.

7. The display substrate according to claim 5 or 6, further comprising: a pixel defining layer arranged on a side of the chiral liquid crystal layer facing the base substrate; wherein
the pixel defining layer comprises a plurality of pixel openings, the light-emitting devices are located in the pixel openings; and
the orthographic projection of the chiral liquid crystal layer on the base substrate is located within an orthographic projection of the pixel opening where the light-emitting device overlapped with the chiral liquid crystal layer is, on the base substrate; or
the pixel defining layer comprises a plurality of pixel openings, the light-emitting devices are located in the pixel openings; and
the orthographic projection of the chiral liquid crystal layer on the base substrate covers and is larger than an orthographic projection of the pixel opening where the light-emitting device overlapped with the chiral liquid crystal layer is, on the base substrate.

8. (canceled)

9. The display substrate according to claim 7, wherein a percentage of an area of the orthographic projection of the chiral liquid crystal layer on the base substrate to an area of the orthographic projection of the pixel opening overlapped with the chiral liquid crystal layer on the base substrate, is negatively correlated with a lifetime decay rate of the light-emitting device overlapped with chiral liquid crystal layer.

10. The display substrate according to claim 3, further comprising: a pixel defining layer arranged on a side of the chiral liquid crystal layer facing the base substrate; wherein
the pixel defining layer comprises a plurality of pixel openings, the light-emitting devices are located in the pixel openings; and
the orthographic projection of the chiral liquid crystal layer on the base substrate approximately coincides with an orthographic projection of the pixel opening where the light-emitting device overlapped with the chiral liquid crystal layer is, on the base substrate.

11. The display substrate according to claim 5, wherein an average refractive index and/or a helical pitch of the chiral liquid crystal layers overlapped with the light-emitting devices of different colors are different, or
spiral directions of the chiral liquid crystal layers overlapped with the light-emitting devices of different colors are same.

12. (canceled)

13. The display substrate according to claim 2 any one of claims 2, wherein the first light-emitting device is a red light-emitting device, the second light-emitting device is a green light-emitting device, and the third light-emitting device is a blue light-emitting device.

14. The display substrate according to claim 1 any one of claims 1, wherein the anti-reflection layer is a circular polarizer.

15. The display substrate according to claim 14, further comprising: a light-absorbing layer arranged between the layer where the light-emitting devices are located and the chiral liquid crystal layer; and
an orthographic projection of the light-absorbing layer on the base substrate approximately coincides with an orthographic projection of a pixel defining layer on the base substrate.

16. The display substrate according to claim 15, further comprising: a first inorganic encapsulation layer, an organic encapsulation layer and a second inorganic encapsulation layer arranged in sequence on a side of the light-emitting device facing the chiral liquid crystal layer;
the light-absorbing layer is arranged between the first inorganic encapsulating layer and the organic encapsulating layer, or the light-absorbing layer is arranged between the second inorganic encapsulating layer and the chiral liquid crystal layer.

17. The display substrate according to claim 15, further comprising: a touch functional layer arranged between the layer where the light-emitting devices are located and the chiral liquid crystal layer; and
wherein the light-absorbing layer is arranged between the touch function layer and the chiral liquid crystal layer.

18. The display substrate according to claim 6 any one of claims 6, wherein the anti-reflection layer is a color filter layer, the color filter layer comprises a black matrix and a plurality of color resistors separated by the black matrix; wherein, orthographic projections of the color resistors on the base substrate approximately coincide with orthographic projections of the pixel openings on the base substrate, and an orthographic projection of the black matrix on the base substrate approximately coincides with an orthographic projections of the pixel defining layer on the base substrate.

19. The display substrate according to claim 18, wherein an display area of the display substrate comprises a left frame area and a right frame area, wherein a spiral direction of the chiral liquid crystal layer in the left frame area is opposite with a spiral direction of the chiral liquid crystal layer in the right frame area; and a total number of the light-emitting devices in the left frame area is equal to a total number of the light-emitting devices in the right frame area.

20. The display substrate according to claim 19, wherein the left frame area and the right frame area are areas on both sides of a column direction symmetry axis of the display area; or
the left frame area and the right frame area are alternately arranged in a row direction and/or a column direction, and each of the left frame area or each of the right frame area comprises at least one light emitting device.

21. (canceled)

22. The display substrate according to claim 1, wherein a center of the orthographic projection of the chiral liquid crystal layer on the base substrate approximately coincides with a center of an orthographic projection of the light-emitting device overlapped with the chiral liquid crystal layer on the base substrate.

23. A display device, comprising a display substrate, wherein the display substrate comprises:
a base substrate;
a plurality of light-emitting devices with a plurality of colors, arranged in an array on the base substrate;
an anti-reflection layer, arranged on a side of a layer where the light-emitting devices are located facing away from the base substrate; and
a chiral liquid crystal layer, arranged between the layer where the light-emitting devices are located and the anti-reflection layer;
wherein an orthographic projection of the chiral liquid crystal layer on the base substrate overlaps with an orthographic projection of at least one color light-emitting device on the base substrate;
a central reflection wavelength of the chiral liquid crystal layer is approximately same as an emission wavelength of the at least one color light-emitting device overlapping with the chiral liquid crystal layer; and
a spiral direction of the chiral liquid crystal layer is left-handed or right-handed.
